(19) United States
(12) Patent Application Publication
(10) Pub. No.: US 2026/0005124 A1
(43) Pub. Date: Jan. 1, 2026

(54) METHOD FOR PRODUCING A SEMICONDUCTOR ASSEMBLY COMPRISING A SEMICONDUCTOR ELEMENT AND A SUBSTRATE

(71) Applicant: SIEMENS AKTIENGESELLSCHAFT, München (DE)

(72) Inventor: Jens Schmenger, Forchheim (DE)

(73) Assignee: SIEMENS AKTIENGESELLSCHAFT, 80333 München (DE)

(21) Appl. No.: 18/879,587

(22) PCT Filed: May 10, 2023
(86) PCT No.: PCT/EP2023/062359

§ 371 Date: Dec. 27, 2024

(30) Foreign Application Priority Data
Jun. 29, 2022 (EP) 22181763.8

(51) Int. Cl. H01L 23/498; H01L 23/00; H02M 3/00

(52) U.S. Cl. CPC H01L 23/49861; H01L 23/49844; H01L 24/32; H01L 24/37; H01L 24/40; H01L 24/73; H01L 24/83; H01L 24/84; H01L 24/48; H01L 2224/32227; H01L 2224/32245; H01L 2224/37013; H01L 2224/40229; H01L 2224/48229; H01L 2224/73215; H01L 2224/73221; H01L 2224/73263; H01L 2224/73265; H01L 2224/83208; H01L 2224/84201; H01L 2924/13055; H02M 3/003

(57) ABSTRACT

In a method for producing a semiconductor assembly, a first power contact of a semiconductor element is materially bonded to a first metallization of a substrate, and a second power contact of the semiconductor element is materially bonded to a molded metal body, with the second power contact being arranged on a face of the semiconductor element facing away from the substrate. A metallic contacting element is contacted directly in a planar manner on the molded metal body for contacting the metallic contacting element to the second power contact via the molded metal body. The metallic contacting element is pressed against the semiconductor element via a dielectric pressing element, with a force acting perpendicularly on the semiconductor element being transferred via the dielectric pressing element.

The invention relates to a method for producing a semiconductor assembly comprising a semiconductor element and a substrate.

The invention furthermore relates to a semiconductor assembly comprising a semiconductor element and a substrate.

In addition, the invention relates to a power converter comprising at least one such semiconductor assembly.

Such a semiconductor module assembly is generally used in a power converter. A power converter should, for example, be understood as being a rectifier, an inverter, a converter or a DC-to-DC converter. The semiconductor elements used in the semiconductor module assembly are, inter alia, transistors, diodes, TRIACs or thyristors. The transistors are, for example, embodied as insulated gate bipolar transistors (IGBTs), field effect transistors or bipolar transistors. Such transistors can comprise a control contact and load contacts. Semiconductor elements are usually contacted via bonding wires, which in particular contain aluminum.

The published, unexamined patent application EP 3 958 306 A1 describes a power module comprising at least two power semiconductor assemblies contacted on a substrate and arranged in a housing. In order to improve the reliability of the power module, it is proposed that the power semiconductor assemblies in each case have at least one semiconductor component, wherein the housing has power connectors on opposite sides, wherein the substrate has supply lines from the power connectors to the power semiconductor assemblies, wherein the supply lines are arranged on the substrate in such a way that electrical current is provided in a symmetrical manner.

The published, unexamined patent application WO 2022/002464 A1 describes a power module comprising at least two power units which in each case comprise at least one power semiconductor and a substrate. In order to reduce the installation space required for the power module and improve heat dissipation, it is proposed that the at least one power semiconductor is in each case connected, in particular in a materially bonded manner, to the respective substrate, wherein the substrates of the at least two power units are in each case directly connected in a materially bonded manner to a surface of a common heat sink.

The patent specification DE 20 2012 004 434 U1 describes a molded metal body for creating a connection of a power semiconductor with top-side potential surfaces to thick wires or ribbons, wherein at least one segment is divided off by a molded metal body which projects over one or more surfaces and from which at least one segment is electrically separated from the remaining molded metal body and which segment extends from a contacting section to a potential surface of the power semiconductor to a fastening section for thick wires laterally spaced apart therefrom.

In particular for ever-larger currents that are impressed into the chip with a constant chip area, commonly used bonding wires reach their limits, for example with regard to load cycle durability.

Against this background, it is an object of the present invention to disclose a semiconductor assembly with improved reliability.

This object is achieved according to the invention by a method for producing a semiconductor assembly comprising a semiconductor element and a substrate comprising the following steps: materially bonding a first power contact of the semiconductor element to a first metallization of the substrate and a second power contact of the semiconductor element, said power contact being arranged on a face of the semiconductor element facing away from the substrate, to a molded metal body, contacting a metallic contacting element to the second power contact via the molded metal body, pressing the metallic contacting element against the semiconductor element via a dielectric pressing element, wherein a force acting perpendicularly on the semiconductor element is transferred via the dielectric pressing element, wherein the metallic contacting element is contacted directly in a planar manner on the molded metal body.

Furthermore, the object is achieved according to the invention by a semiconductor assembly comprising a semiconductor element and a substrate, wherein the semiconductor element has a first power contact and a second power contact, wherein the first power contact is connected in a materially bonded manner to a first metallization of the substrate, wherein the second power contact is connected in a materially bonded manner to a molded metal body on a face of the semiconductor element facing away from the substrate, wherein a metallic contacting element is contacted to the second power contact via the molded metal body, wherein the metallic contacting element is pressed against the semiconductor element via a dielectric pressing element, wherein a force acting perpendicularly on the semiconductor element is transferred via the dielectric pressing element, wherein the metallic contacting element is contacted directly in a planar manner on the molded metal body.

In addition, the object according to the invention is achieved by a power converter comprising at least one such semiconductor assembly.

The advantages and preferred embodiments listed below with regard to the semiconductor can be transferred analogously to the power converter and the method.

The invention is based on the idea of improving the load cycle durability of a semiconductor assembly by improved contacting of semiconductor elements. A first load contact of the semiconductor element is connected in a materially bonded manner to a first metallization of a substrate. The first metallization of the substrate can be embodied as structured and arranged on a dielectric material layer, which, inter alia, can contain a ceramic material such as aluminum nitride or aluminum oxide or an organic material. For example, the first metallization is embodied as copper cladding. On a face of the semiconductor element facing away from the substrate, a molded metal body is connected in a materially bonded manner to a second load contact of the semiconductor element. The molded metal body can, inter alia, be embodied as a metal sheet, in particular as a copper sheet. The materially bonded connection of the semiconductor element to the first metallization and to the molded metal body can in each case, inter alia, be produced by soldering, sintering, or also by an adhesive connection, for example with an electrically and thermally conductive adhesive. Alternatively, the molded metal body can be applied to the second load contact of the semiconductor element by means of an additive method, in particular by means of a thermal spraying process, such as cold gas spraying, and in this way can be connected in a materially bonded manner to the second load contact of the semiconductor element.

In a further step, a metallic contacting element is contacted to the second load contact via the molded metal body. The metallic contacting element can, inter alia, be embodied as a thin metal sheet or metal plate, which can be made of copper, aluminum, silver, gold or an alloy thereof, and enables a large contact surface with the molded metal body. The metallic contacting element can in particular be configured to contact the first metallization of the substrate or to be guided to an external connector.

The metallic contacting element is then pressed onto the molded metal body and thus onto the semiconductor element via a dielectric pressing element. The dielectric pressing element can, for example, contain a dielectric elastomer. The pressure is applied by transferring a force acting perpendicularly on the second load contact of the semiconductor element via the dielectric pressing element. In particular, the dielectric pressing element has at least one flat surface, which is placed in a planar manner on the metallic contacting element, wherein the force is then applied to the dielectric pressing element in order to press the dielectric pressing element onto the molded metal body. In this way, comparatively large-area contacting is achieved by the metallic contacting element resulting in a high current-carrying capacity and in particular improving the load cycle durability of the semiconductor assembly. This improves the reliability of the semiconductor assembly, for example when it is installed in a power converter. Moreover, the architecture of the semiconductor assembly is largely retained, in particular compared to a standard bonding process. In addition, such a production process can be easily and inexpensively integrated into a standard series production process.

The metallic contacting element is contacted directly in a planar manner on the molded metal body. Direct contacting is achieved without any further connecting means such as soldering tin or adhesive. Such contacting is simple and reliable, in particular in combination with the pressing.

A further embodiment provides that the semiconductor assembly is encapsulated after the pressing. An encapsulating compound containing silicone, for example, ensures that the required voltage clearances are maintained. Furthermore, such encapsulation serves to protect against harmful environmental influences.

A further embodiment provides that the dielectric pressing element is predominantly elastically deformed during the pressing. For example, the dielectric pressing element contains a dielectric elastomer such as PUR, PVC or silicone. Predominantly elastic deformation ensures sufficient contact pressure, even during load changes and temperature fluctuations, thus achieving improved reliability. Furthermore, differences in height between the semiconductor element and substrate and any tilting of the semiconductor element can be compensated, and this likewise has a positive effect on the reliability of the semiconductor assembly.

A further embodiment provides that the dielectric pressing element is pressed on via a housing cover. The housing cover, which is already present in most cases, is in particular made of a dielectric material, for example a plastic, and is simple and inexpensive to attach permanently to a housing frame, for example by means of screws or adhesion.

A further embodiment provides that, to connect the second power contact, the metallic contacting element is connected in a materially bonded manner to the first metallization of the substrate. The materially bonded connection can, inter alia, be produced by soldering, sintering, or also by adhesion, for example with an electrically and thermally conductive adhesive. Such an arrangement is simple and inexpensive to realize.

A further embodiment provides that, to connect the second power contact, the metallic contacting element is pressed onto the first metallization of the substrate via the dielectric pressing element. Such a connection achieves improved reliability, in particular in the case of frequent load changes and temperature fluctuations.

The following describes and explains the invention in more detail with reference to the exemplary embodiments depicted in the figures.

It is shown in:

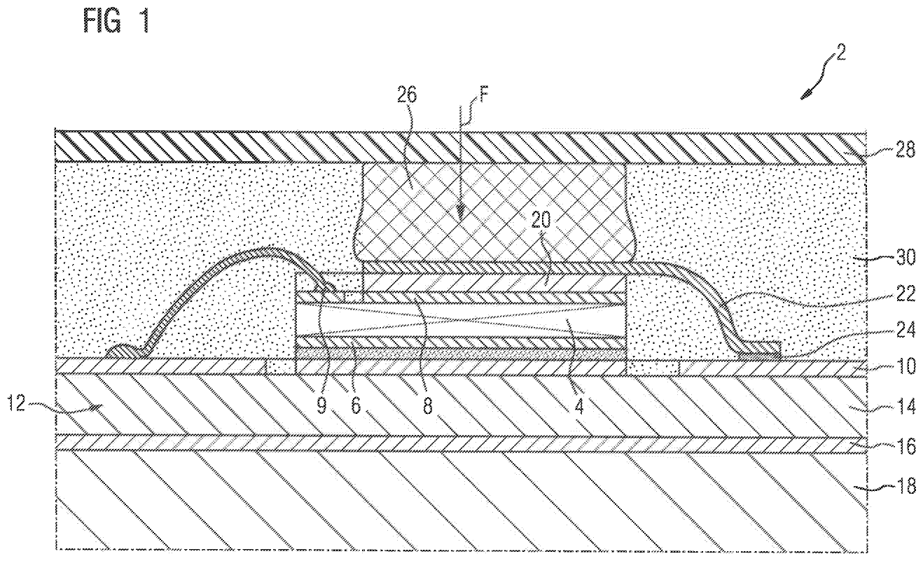

FIG. 1 a schematic cross-sectional view of a first embodiment of a semiconductor assembly,

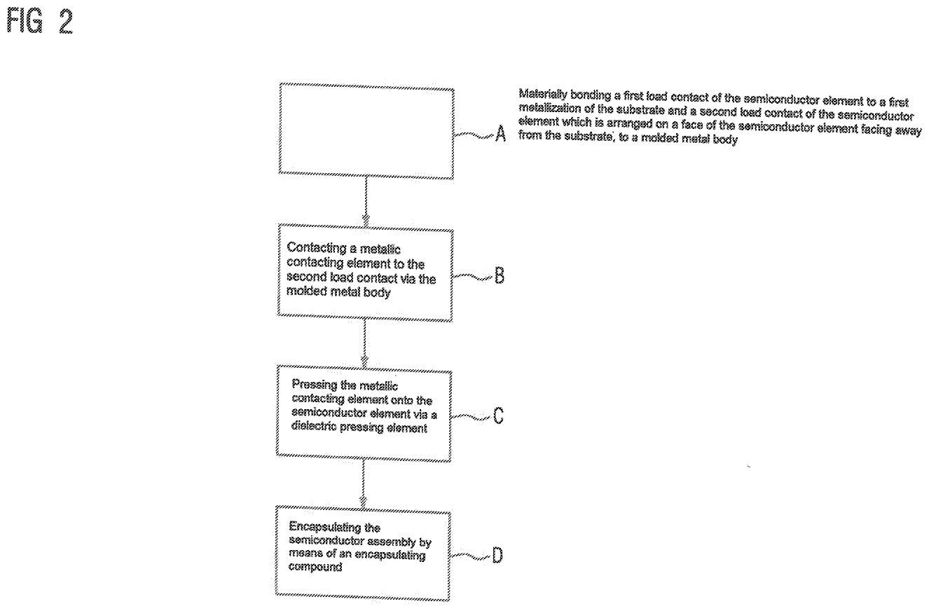

FIG. 2 a flow chart of a method for producing a semiconductor assembly,

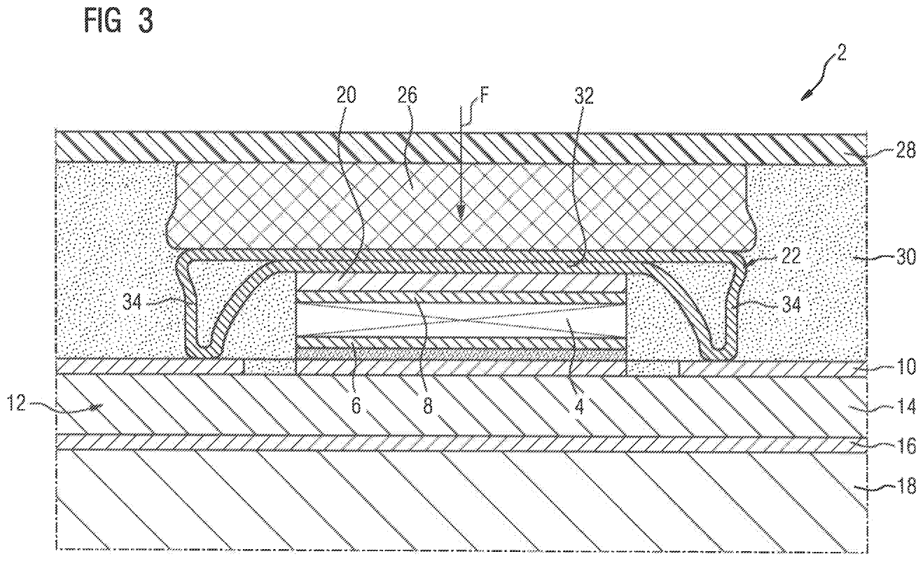

FIG. 3 a schematic cross-sectional view of a second embodiment of a semiconductor assembly,

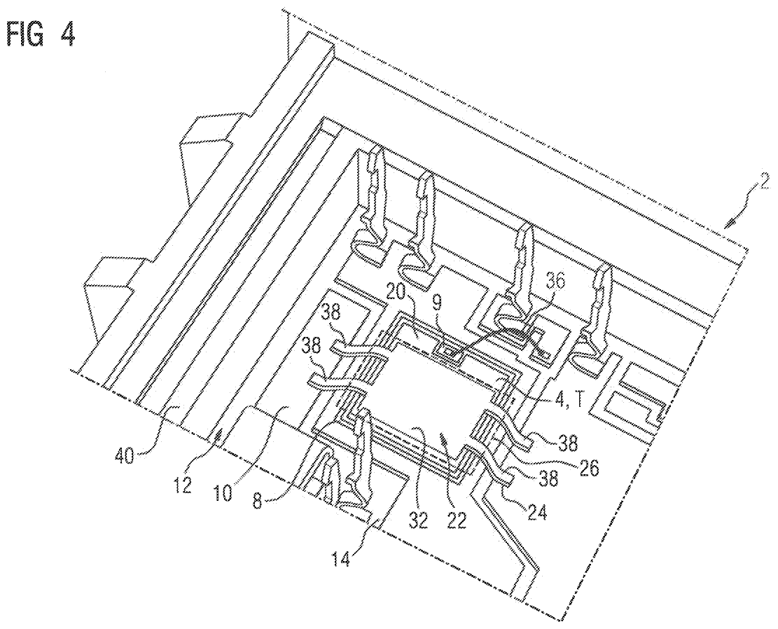

FIG. 4 a perspective schematic section of a third embodiment of a semiconductor assembly,

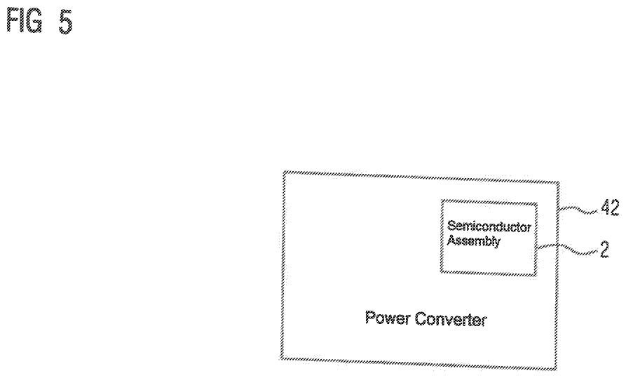

FIG. 5 a schematic view of a power converter.

The exemplary embodiments explained below are preferred embodiments of the invention. In the exemplary embodiments, the described components of the embodiments in each case represent individual features of the invention, which are to be regarded as being independent of one another and which the invention further develops in each case also independently of one another and are therefore to be viewed as part of the invention individually or in a combination other than that shown. Furthermore, the described embodiments can also be supplemented by further features of the invention already described.

In the different figures, the same reference symbols have the same meaning.

FIG. 1 shows a schematic cross-sectional view of a first embodiment of a semiconductor assembly 2 comprising a semiconductor element 4 embodied as a vertical power transistor, in particular as an insulated gate bipolar transistor (IGBT). Further examples of such semiconductor elements 4 are TRIACs, thyristors, diodes or other types of transistors, such as field effect transistors and bipolar transistors. The semiconductor element 4 has a first load contact 6, a second load contact 8 and a control contact 9.

The first load contact 6 of the semiconductor element 4 is connected in a materially bonded manner to a structured first metallization 10 of a substrate 12. The materially bonded connection of the semiconductor element 4 to the substrate 12 can, inter alia, be produced by a soldered connection and/or a sintered connection, or also by an adhesive connection, for example with an electrically and thermally conductive adhesive. In addition, the substrate 12 has a dielectric material layer 14 and a second metallization 16 arranged on a face of the substrate 12 facing away from the first metallization 10. The dielectric material layer 14 can, inter alia, contain a ceramic material, in particular aluminum nitride or aluminum oxide or an organic material. Furthermore, the substrate 12 is connected, in particular in a materially bonded manner, to a heat sink 18 via the second metallization 16, so that the semiconductor element 4 is in an electrically insulating and thermally conductive connection with the heat sink 18 via the substrate.

The second load contact 8 of the semiconductor element 4, which is arranged on a face of the semiconductor element 4 facing away from the substrate 12, is connected in a materially bonded manner to a molded metal body 20, which acts as a buffer layer. For example, the molded metal body 20 is embodied as a metal sheet, which can, inter alia, contain copper, aluminum, silver, gold, molybdenum or an alloy thereof, which is connected to the control-contact contact surface via a sintered connection. Furthermore, the metal sheet can have a coating on one side or both sides, for example to produce a bond connection. Such a coating can, inter alia, contain aluminum, silver, gold, zinc or an alloy thereof. Alternatively, the molded metal body 20 can be applied by means of an additive method, in particular by means of a thermal spraying process, such as cold gas spraying.

Furthermore, a metallic contacting element 22 is electrically conductively connected to the second load contact 8 of the semiconductor element 4 via the molded metal body 20, wherein the metallic contacting element 22 is contacted directly, i.e., without further connecting means, and in a planar manner on the molded metal body 20. The metallic contacting element 22 is substantially embodied as flat in the region of the contacting to the molded metal body 20. In addition, the metallic contacting element 22 is by way of example attached on one face to the first metallization 10 of the substrate 12 via a materially bonded connection 24. The materially bonded connection 24 can, inter alia, be produced by sintering, soldering or a welding process. In particular, the metallic contacting element 22 is produced from copper, aluminum, silver, gold or another alloy.

The metallic contacting element 22 is pressed onto the molded metal body 20 connected to the semiconductor element 4 via a dielectric pressing element 26, which, for example, contains a dielectric elastomer, wherein a force F acting perpendicularly on the semiconductor element 4 is transferred via the dielectric pressing element 26. The dielectric pressing element 26 is predominantly elastically deformed when the metallic contacting element 22 is pressed onto the molded metal body 20. Moreover, the dielectric pressing element 26 in FIG. 1 is pressed against the semiconductor element 4 via a housing cover 28, which is produced from a dielectric material that has lower elasticity than the dielectric pressing element 26. The housing cover 28 is, for example, attached by means of screws or adhesion, to a housing frame, which is not shown in FIG. 1 for reasons of clarity. The housing cover 28 and the dielectric pressing element 26 can be embodied in one piece. In addition, the semiconductor assembly 2 is encapsulated between the housing cover 28 and substrate 12 by means of an encapsulating compound 30, which, for example, contains silicone and serves to maintain the required voltage clearances and to protect against harmful environmental influences.

FIG. 2 shows a flow chart of a method for producing a semiconductor assembly 2, which is, for example, embodied as depicted in FIG. 1. The method comprises materially bonding A a first load contact 6 of the semiconductor element 4 to a first metallization 10 of the substrate 12 and a second load contact 8 of the semiconductor element 4, which is arranged on a face of the semiconductor element 4 facing away from the substrate 12, to a molded metal body 20.

In a further step, a metallic contacting element 22 is contacted B to the second load contact 8 via the molded metal body 20. The profiled contacting element 22 is contacted B directly and in a planar manner on the molded metal body 20.

In a further step, the metallic contacting element 22 is pressed C onto the semiconductor element 4 via a dielectric pressing element 26, wherein the dielectric pressing element 26 is predominantly elastically deformed during the pressing C and a force acting perpendicularly on the semiconductor element 4 is transferred via the dielectric pressing element 26. After the pressing C, the semiconductor assembly 4 is encapsulated D by means of an encapsulating compound 30.

FIG. 3 shows a schematic cross-sectional view of a second embodiment of a semiconductor assembly 2. The metallic contacting element 22 is embodied as a spring sheet with a closed cross section, which has a flat section 32 and elastic sections 34 in the region of the contacting to the molded metal body 20.

The flat section 32 is pressed directly and in a planar manner onto the molded metal body 20 via the dielectric pressing element 26. Furthermore, the elastic sections 34 of the metallic contacting element 22 are pressed on both sides onto the first metallization 10 of the substrate 12, wherein both the elastic sections 34 and the dielectric pressing element 26 are predominantly elastically deformed. In this way, the second load contact 8 of the semiconductor element 4 is connected to the first metallization 10 of the substrate 12 without a materially bonded connection and without connecting means such as soldering tin, sinter paste or adhesive, in particular in a force-fitting manner. The further embodiment of the semiconductor assembly 2 in FIG. 3 corresponds to that in FIG. 1.

FIG. 4 shows a perspective schematic section of a third embodiment of a semiconductor assembly 2 comprising a semiconductor element 4 embodied as a transistor T. The transistor T is embodied by way of example as an IGBT, with a control contact 9 connected via a bonding wire 36 to the first metallization 10 of the substrate 12. The metallic contacting element 22 is embodied as a lead frame and comprises by way of example four supply lines 38 arranged on two sides and connected to the first metallization 10 of the substrate 12 via a materially bonded connection 24. A flat section 32 of the metallic contacting element 22 is pressed onto the semiconductor element 4 by the dielectric pressing element 26, which, for reasons of clarity, is only indicated by dashed lines in FIG. 4. A housing frame 40 completely surrounds the substrate 12. An encapsulating compound, which is delimited by the housing frame 40 and the housing cover, which presses the metallic contacting element 22 onto the molded metal body 20 and thus onto the second load contact 8 of the semiconductor element 4 via the dielectric pressing element 26, is not shown in FIG. 4 for reasons of clarity. The further embodiment of the semiconductor assembly 2 in FIG. 4 corresponds to that in FIG. 1.

FIG. 5 is a schematic view of a power converter 42 comprising a semiconductor assembly 2 by way of example.

In summary, the invention relates to a method for producing a semiconductor assembly 2 comprising a semiconductor element 4 and a substrate 12. In order to improve the reliability of the semiconductor assembly 2, the following steps are proposed: materially bonding A a first power contact 6 of the semiconductor element 4 to a first metallization 10 of the substrate 12 and a second power contact 8 of the semiconductor element 4, said second power contact being arranged on a face of the semiconductor element 4 facing away from the substrate 12, to a molded metal body 20, contacting B a metallic contacting element 22 to the second power contact 8 via the molded metal body 20, pressing C the metallic contacting element 22 against the semiconductor element 4 via a dielectric pressing element 26, wherein a force F acting perpendicularly on the semiconductor element 4 is transferred via the dielectric pressing element 26.

1.-14. (canceled)

15. A method for producing a semiconductor assembly, the method comprising:
materially bonding a first power contact of a semiconductor element to a first metallization of a substrate;
materially bonding a second power contact of the semiconductor element to a molded metal body, with the second power contact being arranged on a face of the semiconductor element facing away from the substrate;
contacting a metallic contacting element directly in a planar manner on the molded metal body for contacting the metallic contacting element to the second power contact via the molded metal body; and
pressing the metallic contacting element against the semiconductor element via a dielectric pressing element, with a force acting perpendicularly on the semiconductor element being transferred via the dielectric pressing element.

16. The method of claim 15, further comprising encapsulating the semiconductor assembly after the metallic contacting element is pressed against the semiconductor element.

17. The method of claim 15, wherein the dielectric pressing element is predominantly elastically deformed as the metallic contacting element is pressed against the semiconductor element.

18. The method of claim 15, wherein the dielectric pressing element is pressed on via a housing cover.

19. The method of claim 15, further comprising connecting the metallic contacting element in a materially bonded manner to the first metallization of the substrate for connecting the second power contact to the molded metal body.

20. The method of claim 15, further comprising pressing the metallic contacting element onto the first metallization of the substrate via the dielectric pressing element for connecting the second power contact to the molded metal body.

21. A semiconductor assembly, comprising:
a substrate;
a semiconductor element comprising a first power contact which is connected in a materially bonded manner to a first metallization of the substrate, and a second power contact which is connected in a materially bonded manner to a molded metal body on a face of the semiconductor element facing away from the substrate;
a metallic contacting element contacted to the second power contact via the molded metal body, with the metallic contacting element being contacted directly in a planar manner on the molded metal body; and
a dielectric pressing element designed to press the metallic contacting element against the semiconductor element, with a force acting perpendicularly on the semiconductor element being transferred via the dielectric pressing element.

22. The semiconductor assembly of claim 21, further comprising an encapsulating compound for encapsulating the semiconductor assembly.

23. The semiconductor assembly of claim 21, wherein the dielectric pressing element is predominantly elastically deformed as the metallic contacting element is pressed against the semiconductor element.

24. The semiconductor assembly of claim 21, wherein the metallic contacting element is embodied as a metal sheet or lead frame.

25. The semiconductor assembly of claim 21, further comprising a housing cover designed to press the dielectric pressing element against the semiconductor element.

26. The semiconductor assembly of claim 21, wherein the metallic contacting element is connected in a materially bonded manner to the first metallization of the substrate for connecting the second power contact.

27. The semiconductor assembly of claim 21, wherein the metallic contacting element is pressed onto the first metallization of the substrate via the dielectric pressing element for connecting the second power contact.

28. A power converter, comprising a semiconductor assembly, said semiconductor assembly comprising a substrate, a semiconductor element comprising a first power contact which is connected in a materially bonded manner to a first metallization of the substrate, and a second power contact which is connected in a materially bonded manner to a molded metal body on a face of the semiconductor element facing away from the substrate, a metallic contacting element contacted to the second power contact via the molded metal body, with the metallic contacting element being contacted directly in a planar manner on the molded metal body, and a dielectric pressing element designed to press the metallic contacting element against the semiconductor element, with a force acting perpendicularly on the semiconductor element being transferred via the dielectric pressing element.

29. The power converter of claim 28, wherein the semiconductor assembly comprises an encapsulating compound for encapsulating the semiconductor assembly.

30. The power converter of claim 28, wherein the dielectric pressing element of the semiconductor assembly is predominantly elastically deformed as the metallic contacting element is pressed against the semiconductor element.

31. The power converter of claim 28, wherein the metallic contacting element of the semiconductor assembly is embodied as a metal sheet or lead frame.

32. The power converter of claim 28, wherein the semiconductor assembly comprises a housing cover designed to press the dielectric pressing element against the semiconductor element.

33. The power converter of claim 28, wherein the metallic contacting element of the semiconductor assembly is connected in a materially bonded manner to the first metallization of the substrate for connecting the second power contact.

34. The power converter of claim 28, wherein the metallic contacting element of the semiconductor assembly is pressed onto the first metallization of the substrate via the dielectric pressing element for connecting the second power contact.
